(19) United States
(12) Patent Application Publication
(10) Pub. No.: US 2006/0226534 A1
(43) Pub. Date: Oct. 12, 2006

(54) Structure and assembly method of integrated circuit package

(75) Inventors: Kuei-Chen Liang, Hsin-Chu City (TW); Chung-Ju Wu, Kaohsiung City (TW); Chung-Yin Fang, Hsin-Chu (TW)

Correspondence Address: LOWE HAUPTMAN BERNER, LLP, 1700 DIAGONAL ROAD, SUITE 300, ALEXANDRIA, VA, 22314, US

(73) Assignee: Silicon Integrated Systems Corp., Hsin-Chu (TW)

(21) Appl. No.: 11/378,283

(22) Filed: Mar. 20, 2006

(30) Foreign Application Priority Data
Mar. 18, 2005 (TW) 94108516

(51) Int. Cl. H01L 23/04; H01L 21/44

(52) U.S. Cl. 257/698; 257/700; 438/614; 257/E23.02; 257/E23.068

(57) ABSTRACT

A packaging structure and an assembly method are disclosed. A packaging structure includes a substrate, a die, conductive wires, and conductively filled material. The substrate includes a conductive structure, and the conductive wires are insulator-coated. The die is mounted on the substrate, and the conductive wires are connected between the die and the conductive structure. The conductively filled material is formed among the conductive wires. In the assembly method, the die is firstly mounted on the substrate, followed by connecting the conductive wires between the die and the conductive structure, and finally forming the conductively filled material among the conductive wires.

### BACKGROUND OF THE INVENTION

1. Field of the Invention

The present invention generally relates to a packaging structure and its assembly method, and more particularly to a packaging structure and an assembly method with a conductively filled material.

2. Description of the Prior Art

Wire bonding is one of traditional integrated circuits packaging techniques. Signals are transmitted from the pads of die to the bonding fingers of a packaging substrate through bonding wires. The signals are further transmitted through trace routing, conductive vias, low layer circuit, and finally to solder balls.

FIG. 1 is a cross-sectional view illustrating a conventional packaging structure. On the surface of the substrate 118 are bonding fingers 106, and the trace routing 108 connected to the bonding fingers 106. The trace routing 108 is further connected to the conductive vias 110, to the low layer circuit 112, and finally to the solder balls 114. The bonding fingers 106 are usually in rectangular shape and are arranged in row surrounding the die 102. As the bonding fingers 106 are located away from the conductive vias 110, the trace routing 108 is thus necessarily required to connect the bonding fingers 106 and the conductive vias 110. The die 102 is usually attached on the substrate 118 through the silver-filled epoxy 116. The bonding wires 104 then connect between the pads of the die 102 and the bonding fingers 106. Thereafter, molding compound 120 is used to cover the bonding wires 104 to prevent shorting among the bonding wires 104. Finally, a thermally conductive cover structure 122 is formed on the molding compound 120.

As the packaging structures get smaller and its circuitry more complex, the density of the bonding wires greatly increases. Conventional bonding wires are non-insulating to each other, so that they are easily shorted. In order to overcome this problem, the length and the arrangement of the bonding wires should be strictly controlled to lower the probability of shorting. Furthermore, the communication paths between the solder balls and the bonding fingers require large amount of trace routing on both sides of the substrate. Each die therefore needs its custom-made design. In other words, a packaging structure designed for one die is difficult to be adapted to other dies. The custom-made design not only increases stockpiles, but also prolongs time to market or time to be certified. Further, the requirement of inserting shielding wires among the bonding wires makes the process more difficult and costs more. Even the shielding wires can shield off undesired electrical effect, they can not help prevent undesired magnetic effect.

For the reason that conventional packaging structure has complicated trace routing and undesired electromagnetic effect, a need has arisen to propose a packaging structure and its assembly method for effective electrical shielding, and to propose an universal substrate that is adaptable for packaging most types of the dies.

### SUMMARY OF THE INVENTION

In view of the foregoing, it is an object of the present invention to provide an universal substrate that is adaptable for packaging most types of the dies. The use of the substrate also simplifies the trace routing, reduces the cost, and prevents shorting.

Another object of the present invention is to provide a packaging structure with effective electrical and magnetic shielding. The packaging structure effectively distributes the grounding, and therefore simplifies the circuit layout and decreases the cost.

According to the object, one embodiment of the present invention provides a packaging structure and an assembly method thereof. A substrate includes pads (such as bonding fingers), conductive vias formed below or beside the pads, and solder balls. After a die is mounted on the substrate, insulator-coated wires are bonded. Accordingly, the present invention can be universally adaptable for packaging dies, simplify the circuit layout, and prevent shorting. Thereafter, conductively filled material is filled onto the die and the substrate, thereby effectively providing electrical and magnetic shielding.

### BRIEF DESCRIPTION OF THE DRAWINGS

FIG. 1 is a cross-sectional view illustrating a conventional packaging structure;

FIG. 2 is a cross-sectional view illustrating a packaging structure according to one embodiment of the present invention;

FIG. 3A to FIG. 3H illustrate an assembly method for packaging an integrated circuit according to one embodiment of the present invention;

FIG. 4 is a cross-sectional view illustrating a packaging structure according to the second embodiment of the present invention;

FIG. 5 is a cross-sectional view illustrating a packaging structure according to the third embodiment of the present invention;

FIG. 6A and FIG. 6B are cross-sectional views illustrating packaging structures according to the fourth embodiment of the present invention;

FIG. 7A to FIG. 7C are cross-sectional views illustrating packaging structures according to the fifth embodiment of the present invention;

FIG. 7D is a perspective view illustrating attaching dies on the substrate of the present invention;

FIG. 7E is a top view illustrating forming an insulating layer between the die and the stop element of the present invention;

FIG. 8A to FIG. 8C are cross-sectional views illustrating packaging structures according to the sixth embodiment of the present invention; and

FIG. 9 schematically shows the QFP, in which the pads of the die are connected to conductive structure through conductive wires to transmit signals.

### DETAILED DESCRIPTION OF THE INVENTION

The following is the detailed description of the embodiments of the present invention. It is appreciated that the processes and structures described below do not entirely encompass whole processes and structures. The present invention could be practiced in conjunction with various fabrication techniques, and only the commonly practiced processes are included to provide an understanding of the present invention.

FIG. 2 is a cross-sectional view illustrating a packaging structure according to one embodiment of the present invention. A packaging substrate 218 (abbreviated as substrate hereinafter) includes a first conductive structure 208, a second conductive structure 214, and a connective structure 211. In the present embodiment, the first conductive structure 208 is formed on one surface of the substrate 218. The first conductive structure 208 could be a pad or a bonding finger. The first conductive structure 208 could have a shape of block or ball, or other shapes suitable for connecting to a wire according to the design of the packaging structure. The second conductive structure 214 is formed on the other surface of the substrate 218. The second conductive structure 214 could be a solder ball, a pin, a lead, a pad, a bonding finger, or other types of structures that are designed according to the demand of packaging specification. In the present embodiment, there are vias 212 formed within the substrate 218. The vias 212 could be through vias that pass through the substrate 218, blind vias that do not pass through the substrate 218, or buried vias that are located inside the substrate 218. The connective structure 211 is formed in the via 212, and is connected between the first conductive structure 208 and the second conductive structure 214. The connective structure 211 could be formed, for example, by applying electrically conductive material (such as copper or other conductive metal) on the internal sides of the via 212, or by filling the via 212 with the electrically conductive material. For the latter case, the filled via 212 integrally comprises the first conductive structure, the connective structure, and the second conductive structure. The boundary between the first conductive structure and the connective structure, or the boundary between the connective structure and the second conductive structure is not specifically and visually defined.

A die (or chip) 202 is fastened on the substrate 218. In this embodiment, the chip 202 is attached (or bonded) on the substrate 218 through die-attach material 206, although other fastening techniques could be adapted. The die-attach material 206 could be electrically insulating material such as epoxy resin, or electrically conductive material such as solders or silver-filled epoxy.

In this embodiment, the ground of the packaging structure is distributed by interconnections among the die paddle (which carries the die 202 and is on the substrate 218) and a ground structure such as ground openings 207 (which electrically connect to the ground). At least one insulator-coated conductive wire 204 connects between the pad of the die 202 and the conductive structure 209. The conductive wire 204 could be insulator-coated gold wire, or the X-Wire™ manufactured by Microbonds incorporation. In this embodiment, an insulating layer 210 is formed to cover the connected-region where the conductive wire 204 is connected to the pad (not shown) of the die 202. Another insulating layer 210 is also formed to cover the connected-region where the conductive wire 204 is connected to a bonding pad, such as a bonding finger (now shown) on the substrate 218, wherein the bonding pad is electrically connected to the conductive structure 209. A stop element 216 is formed on the substrate 218 to confine the formation of the insulating layer 210. In this embodiment, the stop element 216 has a protruding structure, but, however, the stop element 216 could have a concave structure to confine the edges of the insulating layer 210. The stop element 216 may be omitted under some circumstances. For example, the insulating layer 210 could be controllably spread at a predefined region on the substrate 218 if the insulating layer 210 is formed by a syringe transfer process. The stop element 216 may also be omitted if the formed insulating layer 210 can be trimmed or the extended insulating layer 210 beyond the substrate 218 can fall off the substrate 218 by itself. Moreover, if the insulating layer 210 is formed by sputtering, deposition, or other process that can directly control the forming range, the stop element 216 may accordingly be omitted.

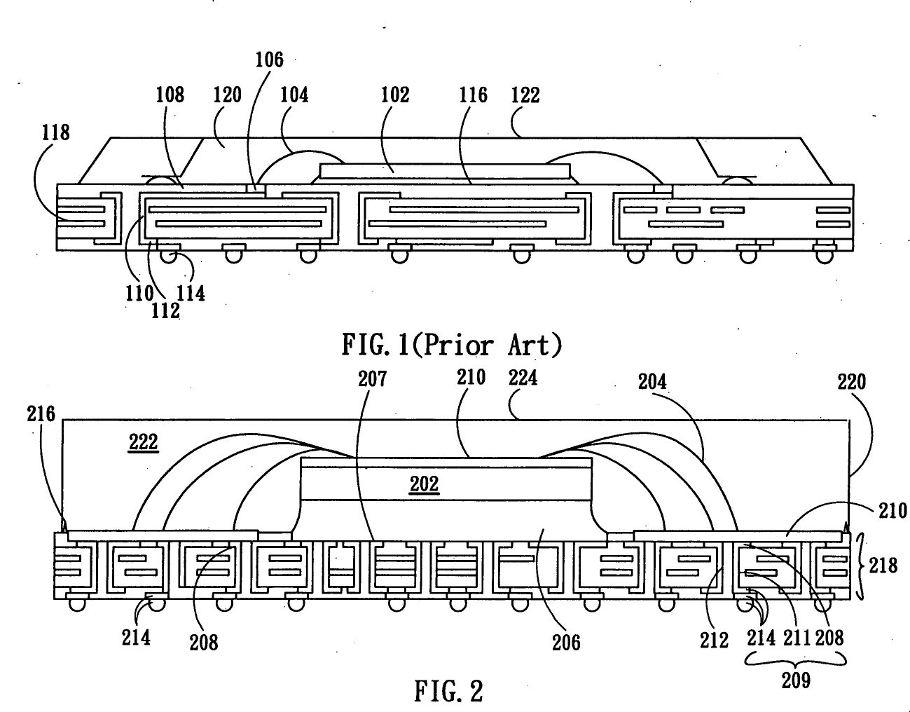

A conductively filled material 222, such as silver-filled epoxy, is formed among the conductive wires 204. In this embodiment, the conductively filled material 222 is in contact with the die-attach material 206, and ultimately electrically connected to the ground openings 207, thereby shielding off the undesired electrical and magnetic effect among the conductive wires 204. There are many methods for forming the conductively filled material 222. In this embodiment, an insulating structure 220, such as a wall frame, is formed on the substrate 218 to confine the distribution of the conductively filled material 222. Other further structures could be formed within the packaging structure. For example, a cover structure 224, such as a thermally conductive cover 224 of FIG. 2 or the thermally conductive cover 122 of FIG. 1, could be formed on the insulating structure 220. It is appreciated that not only traditional structures but also improved structures could be formed within the packaging structure. For example, traces are routed on the substrate 218 for providing signal paths from the bonding fingers to the vias. However, in this embodiment, there is no need of traces routed on the substrate 218 because the signals can be transmitted directly from the pads of the die 202 to the pads of the substrate 218 through the conductive wires 204. Accordingly, this substrate 218 becomes a universal substrate that can be adapted to different types of dies.

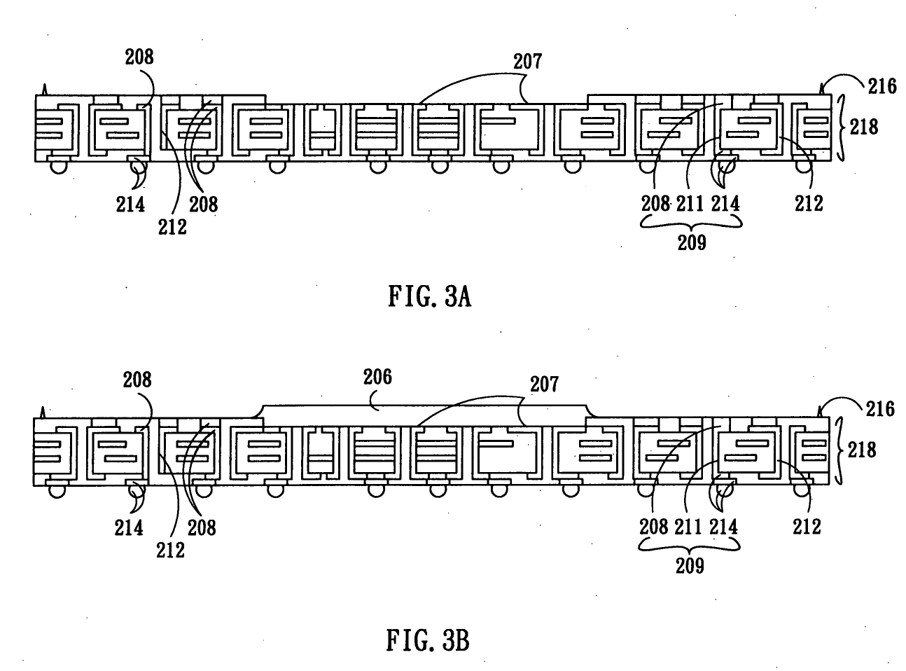

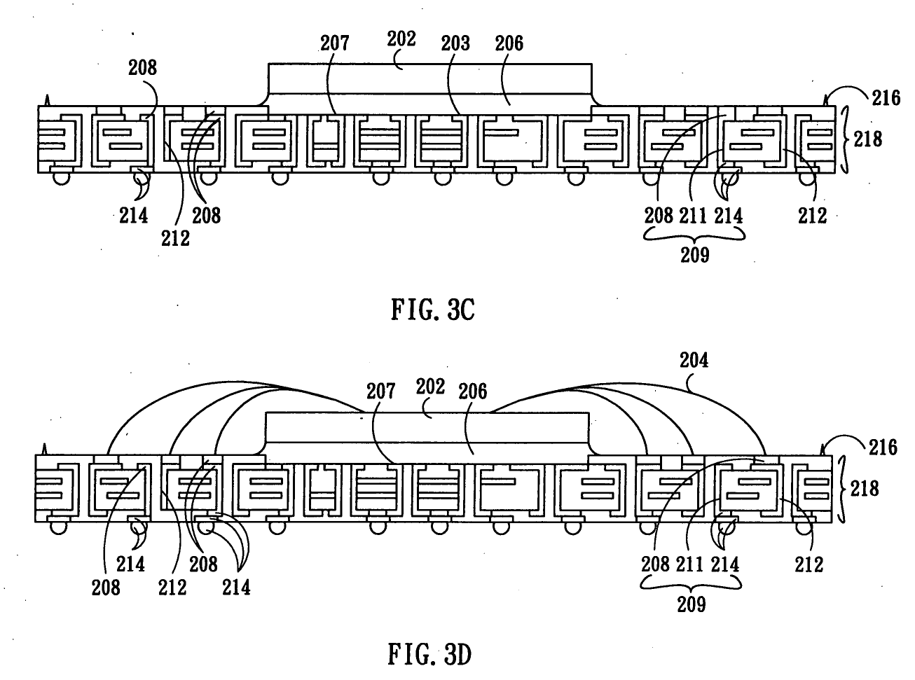

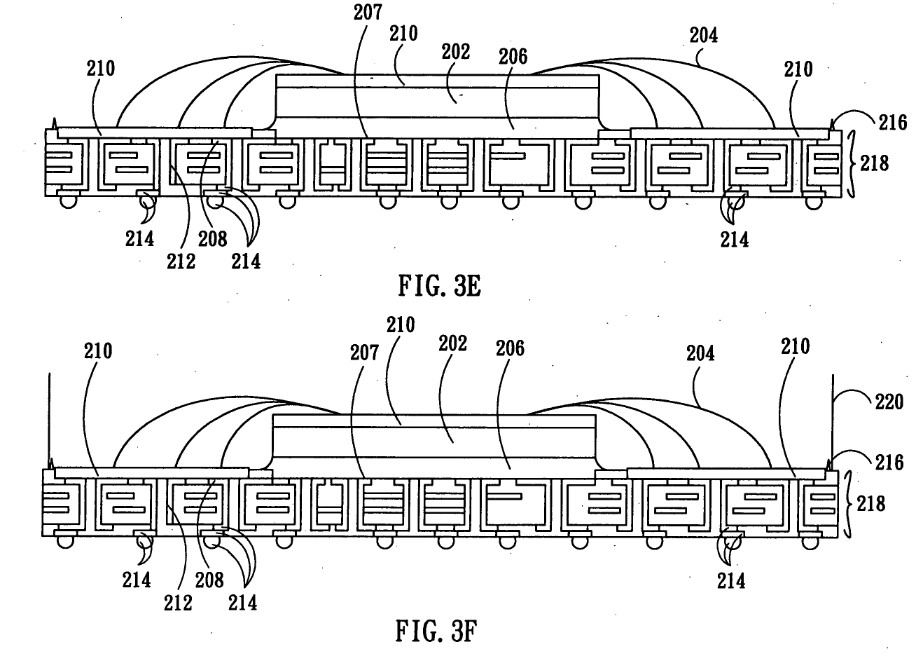

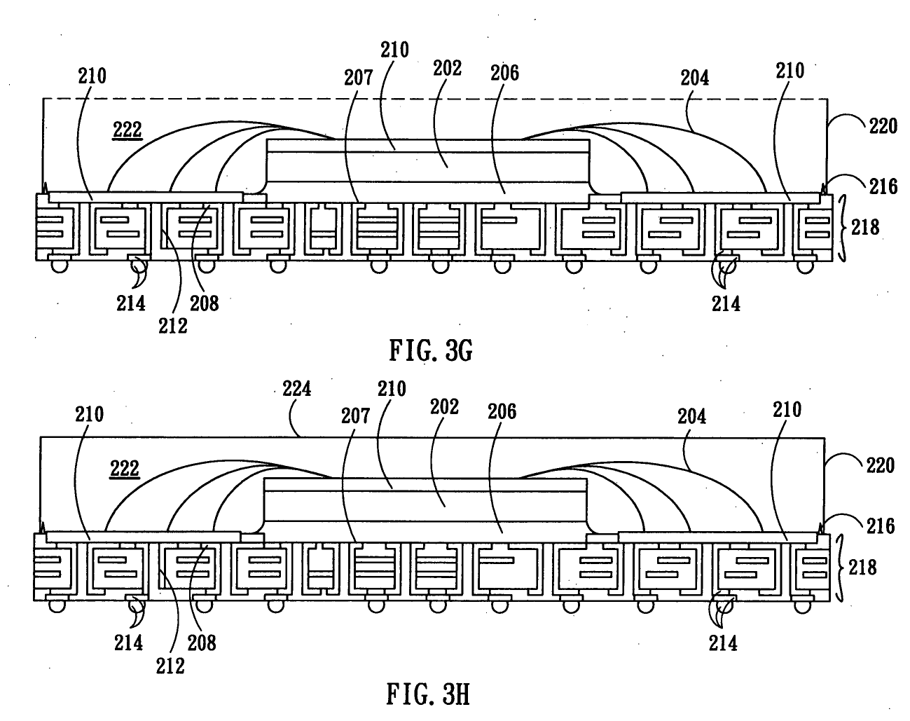

FIG. 3A to FIG. 3H illustrate an assembly method for packaging an integrated circuit according to one embodiment of the present invention. Firstly, in FIG. 3A, a substrate 218 including at least one conductive structure 209 is provided. As shown in FIG. 3B, a die-attach material 206 is formed on the substrate 218, followed by fastening a die 202 onto the substrate 218 through the die-attach material 206 as shown in FIG. 3C. The die-attach material 206 makes the die 202 immovable on the substrate 218 in this embodiment. Next, in FIG. 3D, at least one conductive wire 204 is connected between a bonding pad (not shown) of the die 202 and a bonding pad (not shown) of the substrate 218. As shown in FIG. 3E, an insulating layer 210 is formed to cover a connected-region where the conductive wire 204 connects to the bonding pad of the die 202, and where the conductive wire 202 connects to the bonding pad of the substrate 218. In this embodiment, an insulating structure 220 is formed on the substrate 218 as shown in FIG. 3F. Thereafter, a conductively filled material 222 is formed among the conductive wires 204 as shown in FIG. 3G. Finally, in FIG. 3H, an insulating structure 220 is used to confine the distribution of the conductively filled material 222. In this embodiment, a cover structure 224 is further formed on the insulating structure 220.

Specifically, as shown in FIG. 3A, a substrate 218 having a conductive structure 209 is provided. In this embodiment, the substrate 218 includes a first conductive structure 208, a second conductive structure 214, and a connective structure 211. The first conductive structure 208 is formed on one surface of the substrate 218, and the second conductive structure 214 is formed on the other surface of the substrate 218. In the present embodiment, there are vias 212 formed beside or under the first conductive structure 208. The second conductive structure 214 is formed beside the via 212, or is formed under to cover the via 212. The vias 212 pass through the substrate 218, and the connective structure 211 is formed in the via 212. Accordingly, the first conductive structure 208 and the second conductive structure 214 are electrically connected through the connective structure 211. The connective structure 211 could be formed, for example, by applying electrically conductive material on the internal sides of the via 212, or by filling the via 212 with the electrically conductive material as in the present embodiment. The ground of the packaging structure is distributed by interconnections among the die paddle (which carries the die 202 and is on the substrate 218) and the ground openings 207 (which electrically connect to the ground). The ground of the packaging structure, however, may be provided by other ground structures other than the ground openings 207.

As discussed above, the substrate 218 of the present embodiment could be used as a universal substrate that does not need custom-made trace routing. Accordingly, cost can be reduced, and a substantial quantity of the substrates may be in stock to guarantee the time to market, the time to be certificated, and the availability.

Referring to FIG. 3B, a die-attach material 206 is formed on the substrate 218 for fastening a die 202 on the substrate 218. The formation of the die-attach material 206 could be performed by syringe transfer process or other suitable techniques. In this embodiment, the die-attach material 206 includes an electrically conductive material, which is electrically connected to the ground openings 207.

FIG. 3C shows the resultant view after the die 202 is fastened on the substrate 218. Some die-attach material will naturally harden at room temperature without curing and cooling, while other die-attach material 206 requires curing to be hardened as in the present embodiment.

As shown in FIG. 3D, insulator-coated conductive wires 204 are connected between the die 202 and the conductive structure 209. Specifically, the conductive wires 204 are connected to the first conductive structure 208 of the conductive structure 209 by wire bonding technique in the embodiment. The first conductive structures 208 are capable of accepting the conductive wire 204 from every direction, and therefore the first conductive structures 208 may be arranged in a circular or quasi-circular configuration, or in other configuration, such as square, hollow-circle, or oval. As the surface of the conductive wires 204 is insulator-coated, the conductive wires 204 are electrically insulated from each other. Accordingly, the first conductive structure 208 could be conveniently arranged near or above the associated connective structure 212 of the second conductive structure 214. On the other hand, the first conductive structure 208 disadvantageously needs to be arranged at a place near the pad of the die 202 in the prior art. As the signals can be transmitted directly from the die 202 to the substrate 218 through the conductive wires 204 in the present invention, this substrate 218 becomes a universal substrate that can be adapted for different types of dies.

Referring to FIG. 3E, an insulating layer (or barrier layer) 210 is formed on pertinent areas of the substrate 218 and the die 202. For example, the insulating layer 210 is formed to cover the connected-region where the conductive wire 204 is connected to the conductive structure 209. In this embodiment, a syringe transfer process is utilized to apply (liquid or colloid) non-conductive material onto the die 202 and the substrate 218, followed by curing to make it hardened. The connected-regions where the conductive wires 204 are connected to the pad of the die 202, and the connected-regions where the conductive wires 204 are connected to the first conductive structure 208 are covered by the insulating layer 210, so that current paths are electrically insulated to each other, thereby preventing the circuit shorting among the conductive wires 204. Moreover, a stop element 216 is formed on the substrate 218 to confine the formation of the insulating layer 210.

FIG. 3F shows that an insulating structure 220 is formed on the substrate 218 to confine the distribution of the conductively filled material 222 to be formed in the next step. In addition, the insulating structure 220 could be further used to protect the die 202 from outside effects. For example, the insulating structure 220 could reinforce the packaging structure against deformation. The insulating structure 220 could be also used to block electrostatic discharge (ESD). If the conductively filled material 222 of the next step is of thermosetting type, the insulating structure 220 may be removed after the conductively filled material 222 is hardened, followed by insulator-coating the conductively filled material 222.

As shown in FIG. 3G, a conductively filled material 222 is formed among the conductive wires 204. The resultant conductively filled material 222 could be in solid state or liquid (or colloid) state depending on the application requirement. In this embodiment, silver-filled material is applied, and is then cured to become hardened. Some conductively filled material will become hardened without curing or will be hardened at room temperature; while other conductively filled material will become hardened at a freezing temperature. The silver-filled material of the present embodiment electrically connects to the die-attach material 206, which further connected to the ground openings 207. Accordingly, the conductive wires 204 and the conductively filled material 222 together shield off undesired electrical effect such as electrical crosstalk. Further, the conductive wires 204 and the conductively filled material 222 together eliminate the use of traditional shielding wires. Generally, at least one third of the total wires can be eliminated.

Referring to FIG. 3H, a cover structure 224, such as a thermally conductive cover 224 is formed on the insulating structure 220, thereby finishing the present embodiment.

Regarding the object of electrical shielding, there are other methods other than that discussed above. For example, instead of electrically connecting the conductively filled material 222 to the ground to attain the object, the conductively filled material 222 could be electrically connected to power to attain the same object. Moreover, instead of connecting the conductively filled material 222 to the die-attach material, the conductively filled material 222 could be connected in other ways, which are described in the following paragraphs.

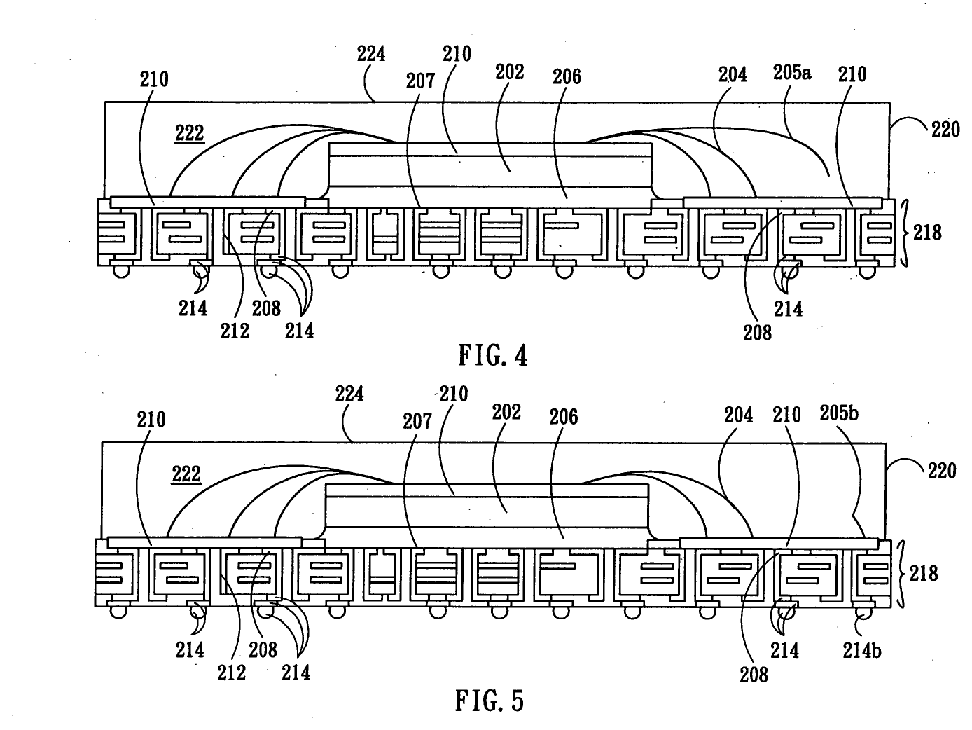

FIG. 4 is a cross-sectional view illustrating a packaging structure according to the second embodiment of the present invention. At least one leading conductor 205a has one end connected to the ground pad of the die 202, and has the other end exposed and floated over the substrate 218. The exposed end of the leading conductor 205a electrically connects to the conductively filled material 222. Accordingly, the die 202 is grounded through the die-attach material 206 and the ground openings 207. As the leading conductor 205a is formed near the conductive wires 204, the generated heat from the die 202 can be substantially dissipated through the conductive wires 204. Besides, the stop element 216 (FIG. 2) is not used to confine the formation of the insulating layer 210 in this embodiment.

FIG. 5 is a cross-sectional view illustrating a packaging structure according to the third embodiment of the present invention. At least one leading conductor 205b has one end connected to the first conductive structure 208 of the substrate 218, and has the other end exposed and floated over the substrate 218. The exposed end of the leading conductor 205b electrically connects to the conductively filled material 222. The conductively filled material 222 and the second conductive structure 214b together are therefore grounded. The object of electrical shielding can be achieved by using either conductive die-attach material 206 or non-conductive die-attach material 206.

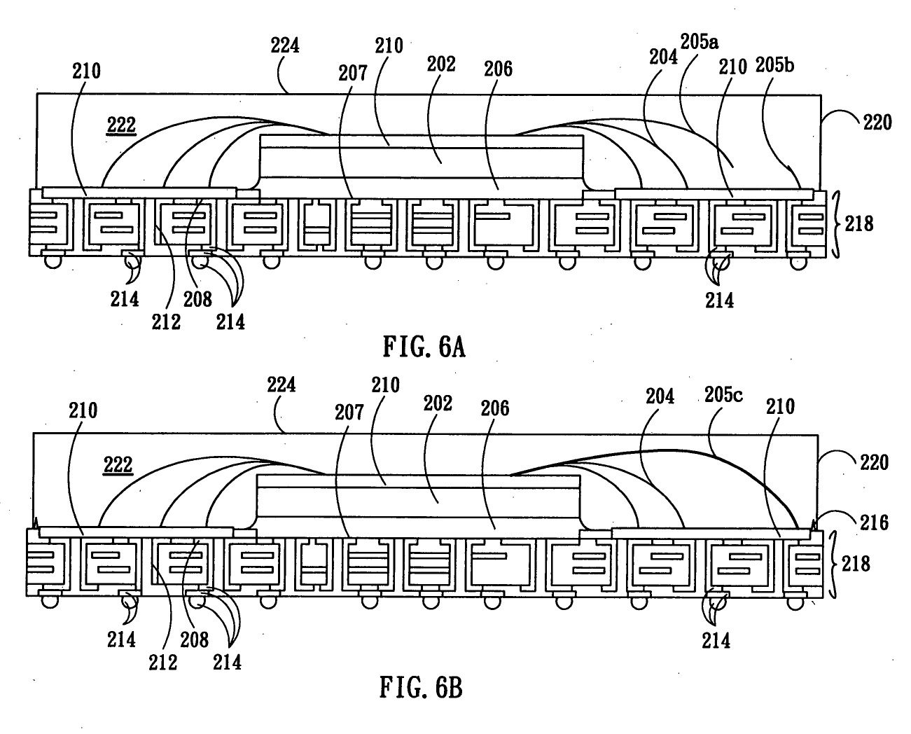

FIG. 6A is a cross-sectional view illustrating a packaging structure according to the fourth embodiment of the present invention. In this embodiment, a leading conductor 205a having one end connected to the ground pad of the die 202 and having the other end exposed and floated over the substrate 218 is used; moreover, another leading conductor 205b having one end connected to the first conductive structure 208 and having the other end exposed and floated over the substrate 218 is also used. The exposed ends of the leading conductor 205a and the leading conductor 205b electrically connect to the conductively filled material 222, and are accordingly grounded with the conductively filled material 222. Therefore, a return path between the substrate 218 and the die 202 is established to substantially shield the electrical effect. FIG. 6B shows an alternative embodiment in which at least one bare (or non-coated) leading conductor 205c is used. The bare leading conductor 205c not only connects between the pad of the die 202 and the first conductive structure 208, but also establishes the grounding through electrically connecting to the conductively filled material 222.

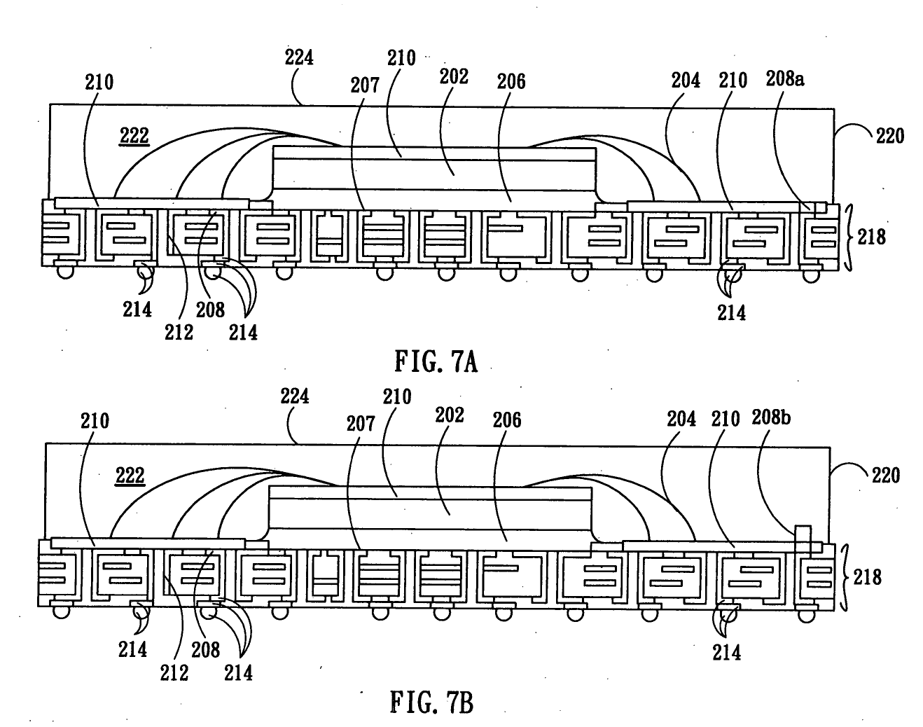

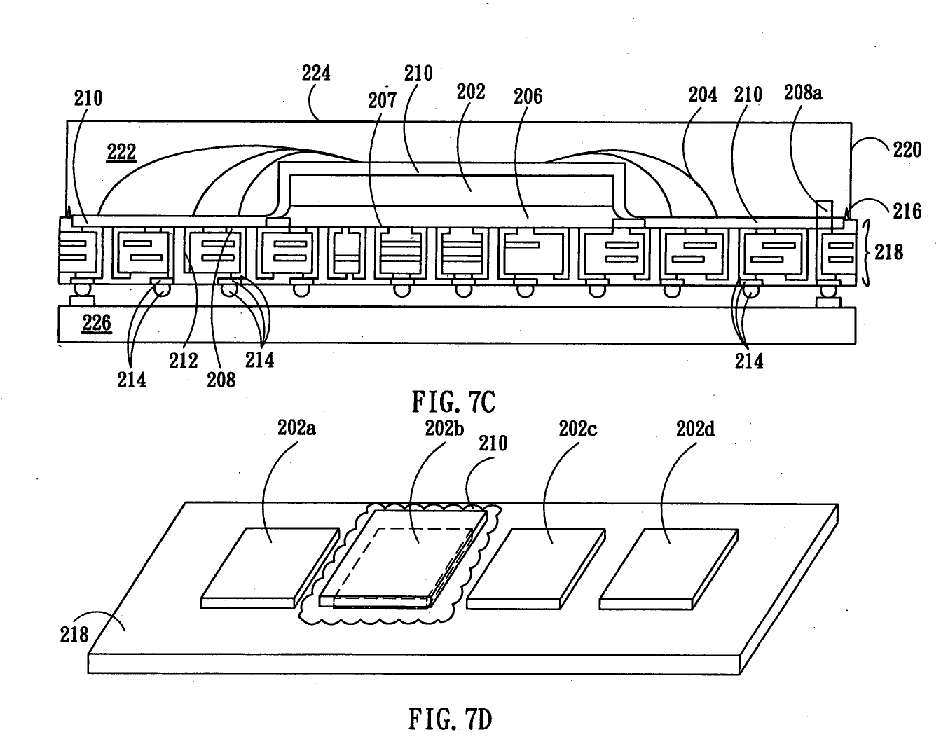

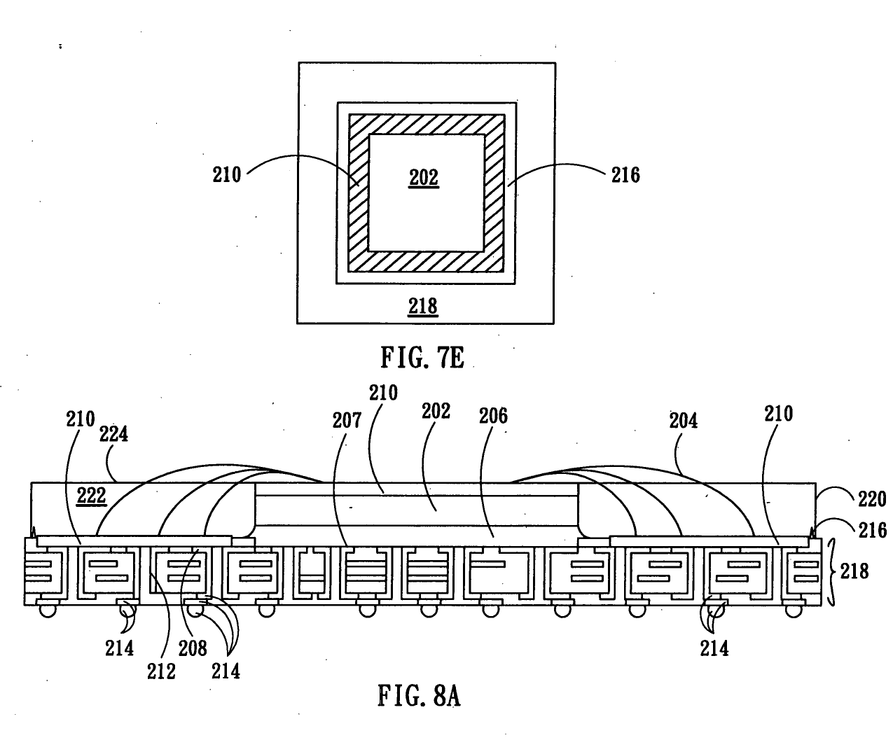

FIG. 7A is a cross-sectional view illustrating a packaging structure according to the fifth embodiment of the present invention. In this embodiment, at least one first conductive structure 208a is not covered by the insulating layer 210, and is thus exposed. The exposed first conductive structure 208a electrically connects to and grounds the conductively filled material 222. Accordingly, a return path is established between the substrate 218 and the die 202. The formation of the exposed first conductive structure 208a is performed by firstly forming epoxy on the surface of the exposed first conductive structure 208a, followed by applying the insulating layer 210. FIG. 7B shows an alternative embodiment in which an exposed first conductive structure 208b protrudes from the substrate 218. During the application of the insulating layer 210, the insulating layer 210 will not accumulate on the protruding portion of the exposed first conductive structure 208b. FIG. 7C shows a further alternative embodiment in which the insulating layer 210 is simultaneously formed on the die 202 and the substrate 218. In this embodiment, a stop element 216 is formed on the substrate 218 to confine the formation of the insulating layer 210.

Still referring to FIG. 7C, the insulator-coated conductive wire 204 could be grounded through an external wire 226. For example, the conductively filled material 222 electrically connects to the exposed first conductive structure 208b, which further electrically connects to the external wire 226 of, for example, a mother board.

FIG. 7D is a perspective view illustrating attaching dies 202a, 202b, 202c, and 202d on the substrate 218, followed by applying an insulating layer 210. The formation of the insulating layer 210 could be either confined or not confined as in this example. The formation of the conductively filled material 222 could be either confined or not confined. The dies 202a, 202b, 202c, and 202d could be either packaged in a single packaging structure or individually packaged in separate packaging structures.

The stop element 216 is formed on the substrate 218 to confine the formation of the insulating layer 210. The stop element 216 could have a wall frame configuration as disclosed in the previous embodiments, however other configuration could also be adapted. FIG. 7E is a top view illustrating forming an insulating layer 210 between the die 202 and the stop element 216. The insulating layer 210 could also cover the top and surrounding of the die 202 and other relevant areas. The stop element 216 may be removed after the insulating layer 210 is formed. The stop element 216 could be also used as the insulating structure 220 to confine the distribution of the conductively filled material 222.

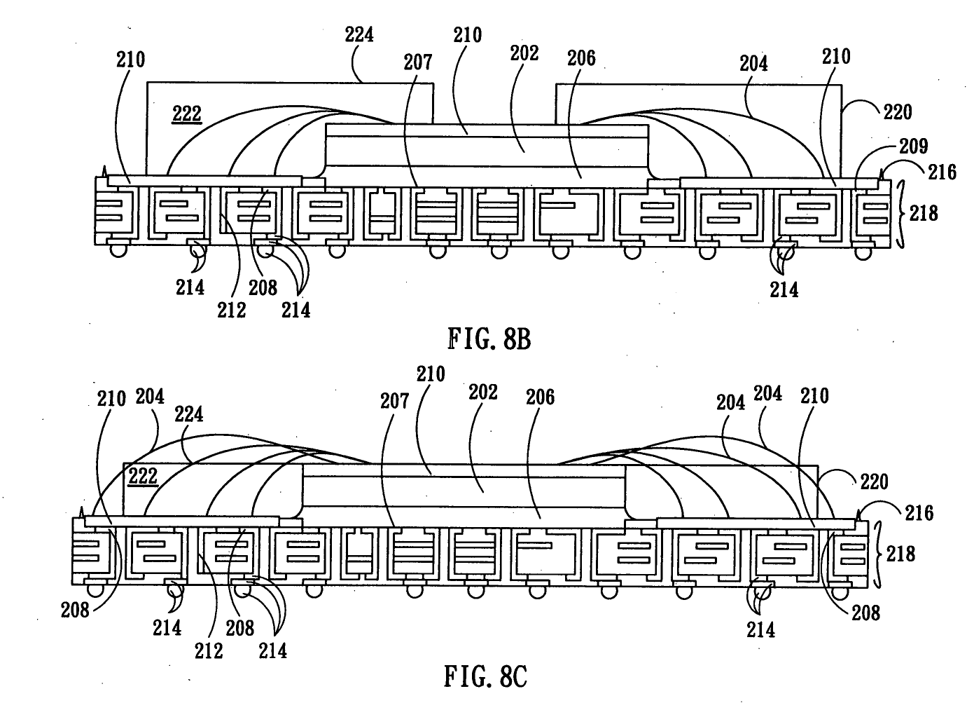

FIG. 8A is a cross-sectional view illustrating a packaging structure according to the sixth embodiment of the present invention. In this embodiment, the conductively filled material 222 is formed on the first conductive structure 208 and among the conductive wires 204, but not on the die 202. FIG. 8B shows an alternative embodiment in which the conductively filled material 222 is formed on a portion of the die 202, and on a portion of the first conductive structure 208. FIG. 8C shows a further alternative embodiment in which the conductively filled material 222 is formed among the conductive wires 204, but not on the die 202, and not on a portion of the first conductive structure 208.

The die-attach material 206 disclosed in some of the previous embodiments is, for example, a conductive silver-filled epoxy, which fastens the die 202 and grounds to the ground openings 207. In other embodiments, an insulating die-attach material is used instead. The die 202, the ground openings 207, and the conductively filled material 222 are electrically connected, and are grounded through other conductive structure, such as the leading conductor. The conductively filled material 222 disclosed in some of the previous embodiments is, for example, a conductive silver-filled epoxy, while other materials could also be used. For example, a liquid (or colloid) instead of solid conductively filled material 222 could be used. The liquid conductively filled material 222 is liquid at room temperature so that the undesired electric and magnetic effect among the conductive wires 204 can be reduced. The composition of the conductively filled material 222 could be selectively varied according to the application requirements. For example, if a phase transition material is used, the conductively filled material 222 will change phase at a specific temperature, such that the heat generated from the die 202 can be efficiently dissipated.

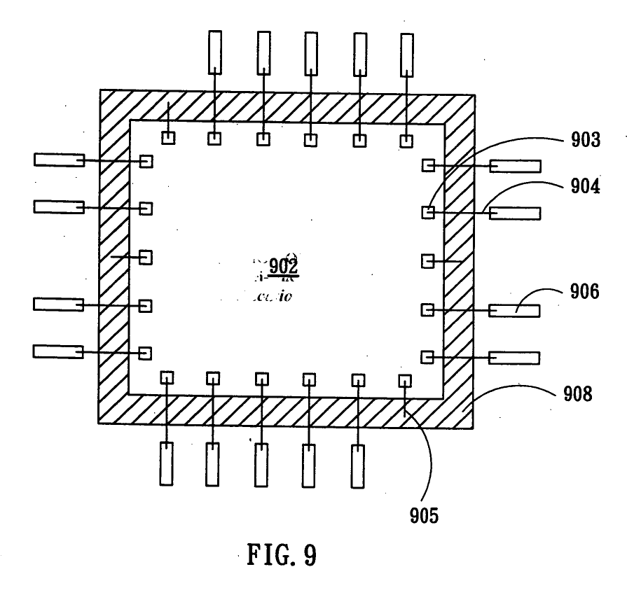

The present invention could be adapted to many package types, such as Plastic Dual-In-line Package (PDIP), Small Outline Package (SOP), Small Outline J-leaded (SOJ) package, or Quad Flat Package (QFP). FIG. 9 schematically shows the QFP, in which the pads 903 of the die 902 are connected to conductive structure 906 (such as leads) through conductive wires 904 to transmit signals. In this example, the conductively filled material 908 is formed between, but not covering, the pads 903 of the die 902 and the conductive structure 906. Various configurations of the conductively filled material 908 and the die 902 disclosed in the previous embodiment could be adapted here. A leading conductor 905 connects between the pads 903 of the die 902 and the conductively filled material 908, thus establishing the grounding. Other grounding techniques disclosed in the previous embodiments could be adapted here.

Although specific embodiments have been illustrated and described, it will be appreciated by those skilled in the art that various modifications may be made without departing from the scope of the present invention, which is intended to be limited solely by the appended claims.

What is claimed is:

1. A packaging structure, comprising:
a substrate including at least one conductive structure;
a die fastened on said substrate by a die-attach material;
a plurality of conductive wires, wherein an insulating material is formed on a surface of said conductive wires, and said conductive wires are electrically connected between said die and said conductive structure in said substrate;
a conductively filled material formed among said conductive wires; and
an insulating layer formed between said conductive structure in said substrate and said conductively filled material, and formed between said conductively filled material and said die respectively.

2. The packaging structure of claim 1, further comprising a ground structure electrically connected to said conductively filled material.

3. The packaging structure of claim 1, wherein said conductive structure comprises:
a first conductive structure having at least one pad formed on one surface of said substrate;
a second conductive structure formed on another surface of said substrate; and
a connective structure formed in said substrate, and connected between said first conductive structure and said second conductive structure.

4. The packaging structure of claim 3, wherein said substrate comprises a plurality of conductive vias, and said connective structure is formed in said conductive via, said first conductive structure being formed beside said conductive via.

5. The packaging structure of claim 3, wherein said first conductive structure comprises at least one pad.

6. The packaging structure of claim 4, wherein said second conductive structure comprises a plurality of solder balls, and said solder balls are formed beside said conductive vias.

7. The packaging structure of claim 4, wherein said second conductive structure covers said conductive via.

8. The packaging structure of claim 1, wherein said conductively filled material is selected from the group consisting of a solid state material, liquid state material, colloid material, and phase change material.

9. The packaging structure of claim 1, further comprising an insulating structure formed on said substrate.

10. The packaging structure of claim 9, further comprising a cover structure formed on said insulating structure.

11. A packaging structure, comprising:
a substrate including at least one conductive structure and a ground structure;
a die fastened on said substrate by a die-attach material;
a plurality of conductive wires, wherein an insulating material is formed on a surface of said conductive wires, and said conductive wires are electrically connected between said die and said conductive structure in said substrate; and
a conductively filled material formed among said conductive wires, and electrically connected to said conductively filled material.

12. The packaging structure of claim 11, wherein said ground structure comprises a ground opening formed in the substrate.

13. The packaging structure of claim 11, wherein said conductive structure comprises:
a first conductive structure having at least one pad formed on one surface of said substrate;
a second conductive structure formed on another surface of said substrate; and
a connective structure formed in said substrate, and connected between said first conductive structure and said second conductive structure.

14. The packaging structure of claim 13, wherein said substrate comprises a plurality of conductive vias, and said connective structure is formed in said conductive via, said first conductive structure being formed beside said conductive via.

15. The packaging structure of claim 13, wherein said first conductive structure comprises at least one pad.

16. The packaging structure of claim 14, wherein said second conductive structure comprises a plurality of solder balls, and said solder balls are formed beside said conductive vias.

17. The packaging structure of claim 14, wherein said second conductive structure covers said conductive via.

18. The packaging structure of claim 11, wherein said die-attach material is conductive, and is electrically connected to said ground structure.

19. The packaging structure of claim 11, wherein said conductively filled material is selected from the group consisting of a solid state material, liquid state material, colloid material, and phase change material.

20. The packaging structure of claim 11, further comprising an insulating structure formed on said substrate.

21. The packaging structure of claim 22, further comprising a cover structure formed on said insulating structure.

22. The packaging structure of claim 11, further comprising a leading conductor, wherein said leading conductor has one end connected to said pad and the other end connected to said conductively filled material.

23. The packaging structure of claim 11, further comprising a leading conductor, wherein said leading conductor has one end connected to said pad and the other end floated in said conductively filled material.

24. The packaging structure of claim 13, wherein a portion of said first conductive structure is exposed and connected to said conductively filled material.

25. The packaging structure of claim 11, further comprising a leading conductor, wherein said leading conductor has one end connected to said pad of the die, and has the other end connected to said conductively filled material.

26. A packaging substrate adaptable to a packaging structure having at least one die and a plurality of conductive wires that are insulator-coated, said packaging substrate comprising:
a substrate having a plurality of conductive vias; and
a conductive structure formed in said substrate;
wherein said conductive wires are electrically connected between said die and said conductive structure in said substrate.

27. The packaging substrate of claim 26, wherein said conductive structure comprises a pin.

28. The packaging substrate of claim 26, further comprising a ground structure formed in said substrate.

29. The packaging substrate of claim 28, wherein said ground structure is formed in ground openings of said substrate.

30. The packaging substrate of claim 26, wherein said conductive structure comprises:
a first conductive structure having at least one pad formed on one surface of said substrate;
a second conductive structure formed on another surface of said substrate; and
a connective structure formed in said conductive via, and connected between said first conductive structure and said second conductive structure.

31. The packaging substrate of claim 30, wherein said pad has a shape of ball.

32. The packaging substrate of claim 30, wherein said first conductive structure is formed on top of said conductive via.

33. The packaging substrate of claim 30, wherein said first conductive structure is formed beside said conductive via.

34. The packaging substrate of claim 30, wherein said second conductive structure comprises a plurality of solder balls.

35. The packaging substrate of claim 30, wherein said second conductive structure is formed at bottom of said conductive via.

36. The packaging substrate of claim 30, wherein said second conductive structure is formed beside said conductive via.

37. A packaging method, comprising:
providing a substrate, said substrate including at least one conductive structure;
fastening a die on said substrate by a die-attach material;
connecting a plurality of conductive wires between said die and said conductive structure in said substrate, wherein an insulating material is formed on a surface of said conductive wires; and
forming a conductively filled material among said conductive wires.

38. The packaging method of claim 37, further comprising forming a ground structure electrically connected to said conductively filled material, and connected to ground with said die-attach material.

39. The packaging method of claim 38, wherein said ground structure is formed in ground opening of said substrate.

40. The packaging method of claim 37, further comprising forming an insulating layer between said conductive structure and said conductively filled material, and between said conductively filled material and said die.

41. The packaging method of claim 38, further comprising forming a leading conductor connected to said conductively filled material and said ground structure.

42. The packaging method of claim 37, wherein said conductive structure is formed by the following steps:
forming a first conductive structure having at least one pad formed on one surface of said substrate;
forming a second conductive structure on another surface of said substrate; and
forming a connective structure in conductive via of said substrate, and connected between said first conductive structure and said second conductive structure.

43. The packaging method of claim 42, further comprising forming a plurality of solder balls as the second conductive structure beside said conductive vias.

44. The packaging method of claim 37, further comprising forming an insulating structure to confine distribution of said conductively filled material.

45. The packaging method of claim 44, further comprising forming a cover structure on said insulating structure.

46. The packaging method of claim 42, further comprising forming a leading conductor, wherein said leading conductor has one end connected to said pad and the other end connected to said conductively filled material.

47. The packaging method of claim 42, further comprising forming a leading conductor, wherein said leading conductor has one end connected to said pad and the other end floated in said conductively filled material.

48. The packaging method of claim 42, further comprising exposing a portion of said first conductive structure and connecting to said conductively filled material.
